(19) United States
(12) Patent Application Publication
(10) Pub. No.: US 2012/0186847 A1
(43) Pub. Date: Jul. 26, 2012

(54) SHIELD FOR INSPECTING ELECTRICAL PANELS

(76) Inventor: PAUL MARTIN, Gilroy, CA (US)

(21) Appl. No.: 13/011,047

(22) Filed: Jan. 21, 2011

(51) Int. Cl. H05K 5/00

(52) U.S. Cl. 174/50

(57) ABSTRACT

An inspection panel comprised of clear polycarbonate sheet, approximating the opening of an electrical power panel, replaces the standard covering, thereby allowing inspection of the wiring and components within the panel. The inspection panel provides protection against an electrical arc or fire, thereby eliminating the need for an inspector to wear protective equipment. The inspection panel may be sized to insert into the box when the standard covering is removed, or the inspection panel may be larger than the panel and be affixed to the panel by fasteners.

### BACKGROUND

Any utility installation or repair in a commercial or public building, and in some cases residential building, requires an inspection by the local authority with responsibility for insuring that the work has been done according to the appropriate code or codes. For example, for an electrical inspection, part of the inspection would typically include inspection of the power panel which may include various circuit breakers, controls, and meters. The inspection may be required to be performed with power applied to the building and connected to the loads, thereby making the power panel hazardous to inspect. If an inspection could be performed without power being applied, it would be disruptive to the occupants to remove power from an entire building, especially a commercial building, to enable a safe inspection. As a result, even if the inspection does not require power to be active at the time of inspection, power may be left connected for the convenience of the occupants. Even with properly grounded devices and ground fault interruption protection, injury or death can result from an arc flash from a make or break connection.

Various codes, for example National Fire Prevention Association standard NFPA 70E HRC2 or OSHA 29 CFR 1910.269, provide for the protection of an inspector or electrician against shock or burn resulting from the arcing that may result when various loads are turned ON or OFF. Equipment meeting the standards include protective clothing and clear face shields, all meeting their various specifications and codes. Importantly, government inspectors are required to be protected during an inspection, thereby fostering the cost of protective equipment upon the inspecting agency. In addition getting the equipment on and off requires a significant time period, causing the agency to need more inspectors. What is needed is a solution allowing inspectors to perform an inspection without needing safety equipment.

### SUMMARY

A typical power panel is constructed from a metal box of five sides. The open side provides access to the enclosed circuit breakers and other devices. A standard metal plate with openings corresponding to the circuit breakers or other devices covers the various wires and connections such that a user may operate the circuit breaker activation levers without being exposed to the high voltage electrical power covered by the standard plate. In the various embodiments, a clear flame inhibiting material replaces the cover of a power panel to be inspected. The replacement can be done by the installing electrician. The installing electrician may put on the safety equipment in preparation for the inspection, then remove the power panel cover, installing the clear flame inhibiting material in place of the panel cover. After the inspection, the installing electrician removes the clear fire inhibiting material and replaces the standard metal cover.

### BRIEF DESCRIPTION OF THE DRAWINGS

The accompanying drawing, which is incorporated herein and constitutes part of this specification, illustrates exemplary aspects of the invention, and, together with the general description given above and the detailed description given below, serves to explain features of the invention.

FIG. 1 is an example of a clear fire inhibiting device for viewing a hazardous area safely.

### DETAILED DESCRIPTION

The various embodiments will be described in detail with reference to the accompanying drawing. References made to particular examples and implementations are for illustrative purposes, and are not intended to limit the scope of the invention or the claims.

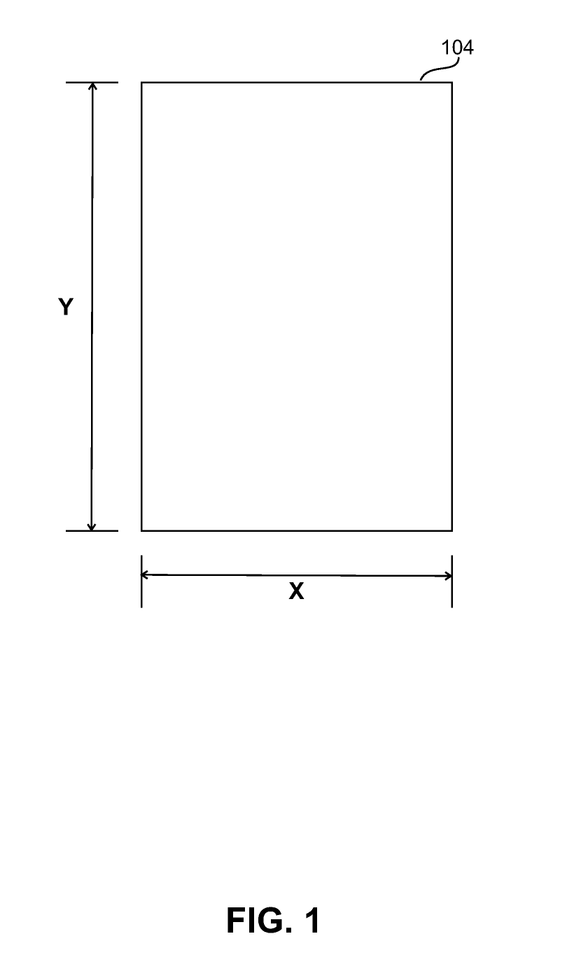

FIG. 1 shows an inspection panel 104, which is a shield for inspecting electrical panels, made of a clear fire inhibiting material. Any material meeting the industry codes, for example National Fire Prevention Association standard NFPA 70E HRC2 or OSHA 29 CFR 1910.269, may be used, thereby providing compliance with NFPA 70 E for blocking exposure to hazardous energies.

An example of a suitable material for the inspection panel 104 is a plate made from Makrolon® F1 flame inhibiting polycarbonate sheet, available from Sheffield Plastics, 119 Salisbury Road, Sheffield, Mass., 01257. In some embodiments the plate is 0.25 inches thick.

The panel 104 illustrated in FIG. 1 is shown in a vertical orientation for the convenience of description, but may be in any orientation corresponding to the panel it will be inserted into. It is usual for power panels to be oriented with the long dimension vertical. A power panel in a commercial installation often has a horizontal dimension of approximately twenty inches in the X direction as shown in FIG. 1. The Y dimension is arbitrary, corresponding to the vertical dimension of a given panel. In a residential installation, where a stud spacing of sixteen inches is standard in the United States, the dimension in the X direction would typically be approximately fourteen inches.

To use the inspection plate 104, the standard plate covering the circuit breakers and any other devices in the box is removed, exposing the wiring to view. The inspection plate 104 is then placed into the now-exposed opening. In some embodiments the plate is sized such that it fits into the opening. In other embodiments the inspection plate 104 is larger than the opening and may be equipped with fasteners (not shown) that attach the inspection plate to the thin metal walls of the power panel. An inspector may then inspect the wiring and components freely without the need for protective equipment of any kind. When the inspection is complete, the inspection plate 104 is removed, and the standard plate replaced.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A portable, removable inspection device for enabling safe observation of wiring and components within an electrical power panel, comprising a clear plate made from a fire-inhibiting material including a thickness, wherein the inspection device is of a size corresponding to a standard covering plate.

2. The inspection device of claim 1, wherein the fire-inhibiting material is flame inhibiting polycarbonate sheet.

3. The inspection device of claim 1, wherein the inspection device is larger than the electrical power panel.

4. The inspection device of claim 3 wherein the inspection device further includes fasteners for fastening the inspection device to the electrical power panel.

5. The inspection device of claim 1, wherein the thickness is 0.25 inches.

6. The inspection device of claim 1, wherein the thickness is less than 0.25 inches.

7. The inspection device of claim 1, wherein the thickness is greater than 0.25 inches.
